(19) United States
(12) Patent Application Publication
(10) Pub. No.: US 2014/0085033 A1
(43) Pub. Date: Mar. 27, 2014

(54) PLANAR MAGNETIC COMPONENT AND METHOD FOR MANUFACTURING THE SAME

(71) Applicant: Shanghai Zhuo Kai Electronic Technology Co., Ltd, Shanghai City (CN)

(72) Inventor: Yao-Long Wen, Chung-Li City (TW)

(73) Assignee: Shanghai Zhuo Kai Electronic Technology Co., Ltd, Shanghai City (CN)

(21) Appl. No.: 14/093,829

(22) Filed: Dec. 2, 2013

(30) Foreign Application Priority Data
Dec. 3, 2012 (CN) 201210509999.3

(51) Int. Cl. H01F 27/24; H01F 41/00

(52) U.S. Cl. CPC H01F 27/24; H01F 41/005
USPC 336/200; 336/233; 427/131

(57) ABSTRACT

A planar magnetic component and a method for manufacturing the same are provided. The planar magnetic component includes a substrate and a magnetic structure embedded in the substrate; wherein the magnetic structure includes a ferromagnetic material layer and at least one first hard protective layer disposed on a first surface of the ferromagnetic material layer to prevent the ferromagnetic material layer from being breaking in a pressing process.

### FIELD OF THE INVENTION

The present invention relates to a magnetic component, and more particularly to a planar magnetic component having an embedded magnetic structure and adapted to be applied in a transformer.

### BACKGROUND OF THE INVENTION

An embedded magnetic component of a traditional transformer suitable for being used in a communication connector is such as an iron core. Generally, the iron core has a main magnetic material of Fe₃O₄. In view of a breakable feature of the iron core, an embedded magnetic component surrounded with a flexible stuff is proposed. A elasticity material such as epoxy resin proposed in U.S. Pat. No. 8,203,418 B2 is used for cushioning a stress resulting from a thermal expansion and contraction in operating element and affecting on the magnetic component to reduce a possibility of breaking the magnetic component. However, the elasticity material such as epoxy resin cannot be used for preventing the iron core from breaking in a pressing process.

In view of the aforementioned reasons, there is a need to provide a new transformer structure having the embedded magnetic component to improve a capability for protecting the iron core and a yield for producing the transformer.

### SUMMARY OF THE INVENTION

The present invention provides a planar magnetic component and a method for manufacturing the same to improve a production yield of a transformer.

In order to achieve the aforementioned advantages or other merits, a planar magnetic component including a substrate and a magnetic structure embedded in the substrate is provided in an embodiment of the present invention. The magnetic structure includes a ferromagnetic material layer and at least one first hard protective layer disposed on a first surface of the ferromagnetic material layer.

In an embodiment of the present invention, the magnetic structure further includes a second hard protective layer disposed at a second surface of the ferromagnetic material layer, wherein the first surface of the ferromagnetic material layer and the second surface of the ferromagnetic material layer are opposite to each other.

In an embodiment of the present invention, the first hard protective layer and the second hard protective layer have a material of a reactive resin having an epoxy group, and the ferromagnetic material layer is an iron core.

In an embodiment of the present invention, the reactive resin having the epoxy group has a glass transition temperature greater than 200° C.

In an embodiment of the present invention, the reactive resin having the epoxy group has a coefficient of thermal expansion greater than or equal to that of the substrate.

In an embodiment of the present invention, the planar magnetic component further includes a first conductor layer disposed on a second surface of the substrate and a second conductor layer disposed over a first surface of the substrate, wherein the first surface of the substrate and the second surface of the substrate are opposite to each other, the second surface of the substrate is away from the magnetic structure, the first surface of the substrate is close to the magnetic structure, and the first hard protective layer is disposed between the ferromagnetic material layer and the second conductor layer.

In an embodiment of the present invention, the planar magnetic component further includes an adhesive layer disposed between the first hard protective layer and the second conductor layer as well as disposed between the substrate and the second conductor layer.

In an embodiment of the present invention, the first conductor layer and the second conductor layer have a material of copper, and the adhesive layer has a material of polypropylene.

In an embodiment of the present invention, the planar magnetic component further includes a plurality of holes and at least one wire, wherein each of the hole penetrates through the second conductor layer, the adhesive layer, the magnetic structure, the substrate, and the first conductor layer, and the wire passes through the hole as well as entwines the magnetic structure, and the substrate is a printed circuit board.

The present invention further provides a method for manufacturing a planar magnetic component, includes steps of providing a substrate having a first surface; forming a recess in the substrate, wherein the recess penetrates through the first surface of the substrate; and forming a magnetic structure in the recess. The step of forming the magnetic structure in the recess includes of forming a ferromagnetic material layer; and forming at least one first hard protective layer on a first surface of the ferromagnetic material layer.

In an embodiment of the present invention, the substrate further includes a zeroth conductor layer disposed on the first surface of the substrate, and the method for manufacturing a planar magnetic component further includes removing the zeroth conductor layer by an etching process before forming the recess in the substrate.

In an embodiment of the present invention, the step of forming a magnetic structure in the recess further includes forming a second hard protective layer on a second surface of the ferromagnetic material layer, wherein the first surface of the ferromagnetic material layer and the second surface of the ferromagnetic material layer are opposite to each other.

In an embodiment of the present invention, the substrate further includes a first conductor layer disposed on a second surface of the substrate, the second surface of the substrate and the first surface of the substrate are opposite to each other.

In an embodiment of the present invention, the method further includes forming an adhesive layer on the first surface of the substrate as well as on a surface of the first hard protective layer away from the ferromagnetic material layer, and the first hard protective layer is disposed between the adhesive layer and the ferromagnetic material layer.

In an embodiment of the present invention, the method further includes forming a second conductor layer on a surface of the adhesive layer away from the first hard protective layer and the first surface of the substrate.

In an embodiment of the present invention, the method further includes forming a plurality of holes, wherein each of the hole penetrates through the second conductor layer, the adhesive layer, the magnetic structure, the substrate, and the first conductor layer, and then at least one wire passes through the hole as well as entwines the magnetic structure, and the substrate is a printed circuit board.

In summary, two hard protective layers respectively disposed on an upper surface and a lower surface of the ferromagnetic material layer of the planar magnetic component is provided to protect and prevent the ferromagnetic material layer from being breaking in a pressing process. So a production yield of a transformer produced with the planar magnetic component could be enhanced.

For making the above and other purposes, features and benefits become more readily apparent to those ordinarily skilled in the art, the preferred embodiments and the detailed descriptions with accompanying drawings will be put forward in the following descriptions.

### BRIEF DESCRIPTION OF THE DRAWINGS

The present invention will become more readily apparent to those ordinarily skilled in the art after reviewing the following detailed description and accompanying drawings, in which:

FIGS. 1A˜1G are schemes illustrating a method for manufacturing a planar magnetic component in accordance with an embodiment of the present invention; and

FIGS. 1H˜1I are schematic diagrams illustrating shapes of a ferromagnetic material layer.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

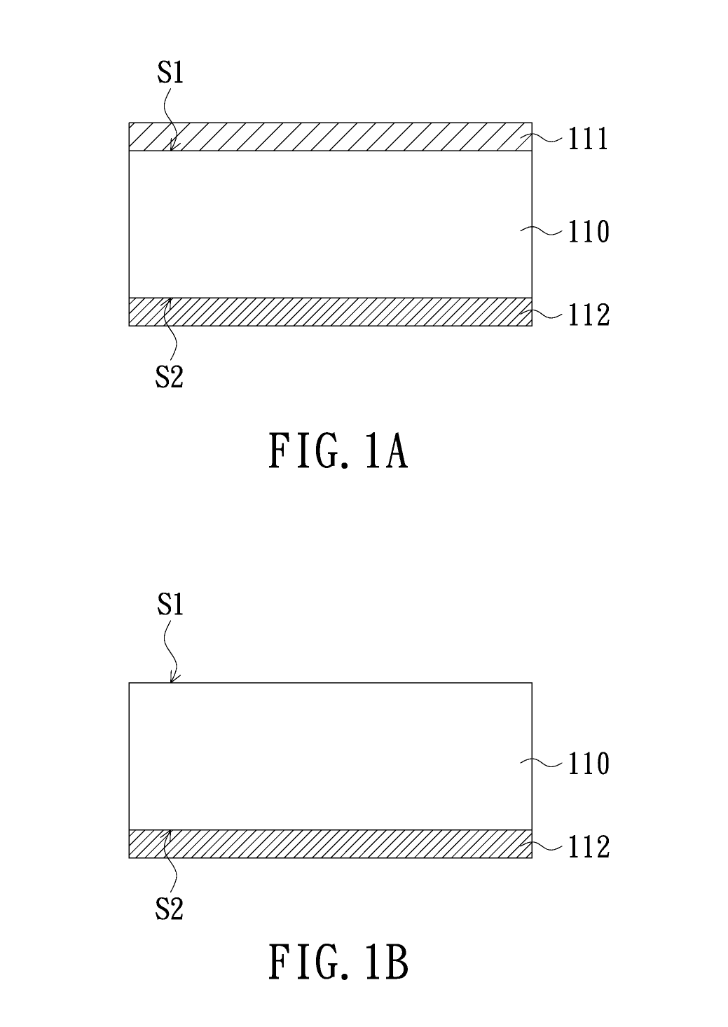

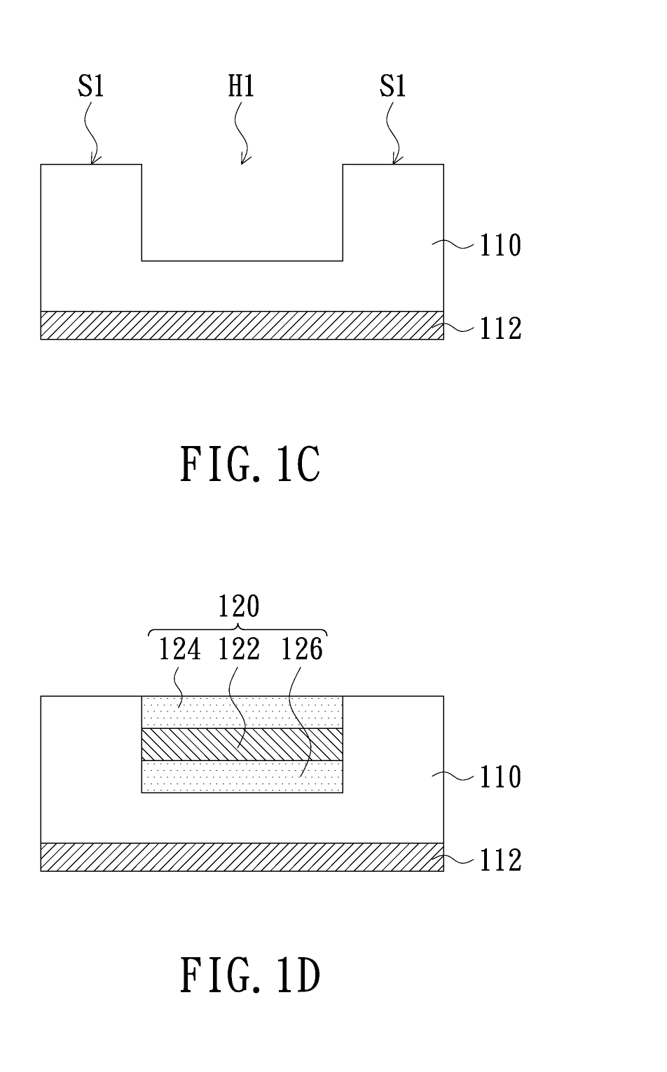

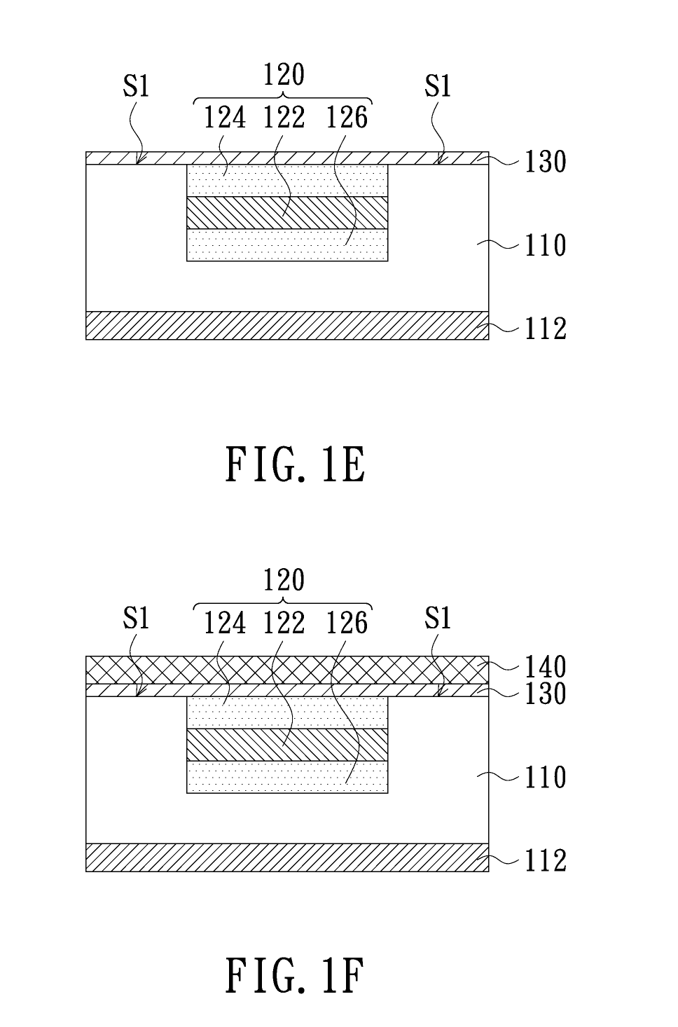

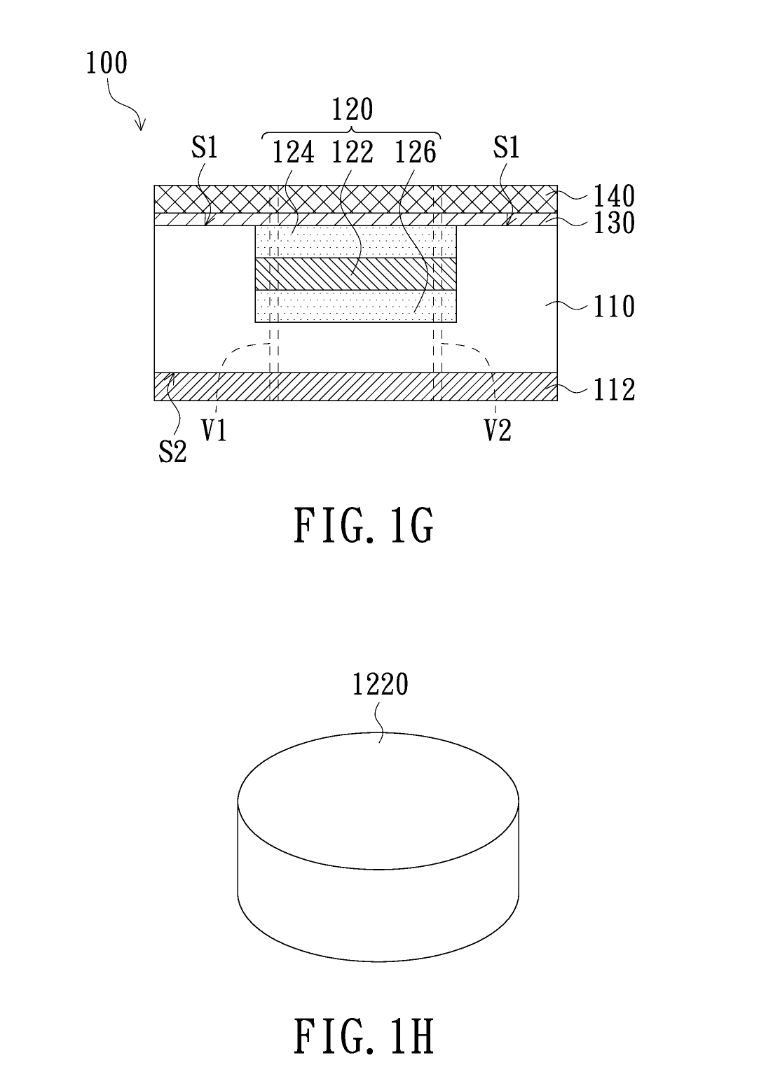

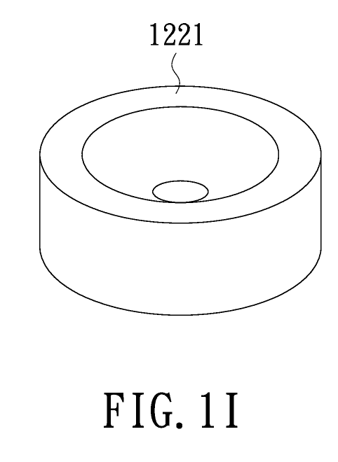

FIGS. 1A˜1G are schemes illustrating a method for manufacturing a planar magnetic component in accordance with an embodiment of the present invention. Please refer to FIG. 1A and FIG. 1B. The method for manufacturing the planar magnetic component includes steps of: providing a substrate 110, wherein the a zeroth conductor layer 111 is formed on a first surface S1 of the substrate 110, a first conductor layer 112 is formed on a second surface S2 of the substrate 110, wherein the first surface Si of the substrate 110 and the second surface S2 of the substrate 110 are opposite to each other (shown in FIG. 1A); removing the zeroth conductor layer 111 from the first surface S1 of the substrate 110 by a etching process (shown in FIG. 1B). The substrate 110 is, for example, a printed circuit board (PCB). The zeroth conductor layer 111 and the first conductor layer 112 have a material such as copper.

Please refer to FIG. 1C and FIG. 1D. After removing the zeroth conductor layer 111, the method further includes steps of forming a recess H1 in the substrate 110, wherein the recess H1 penetrates through the first surface Si of the substrate 110 (shown in FIG. 1C); and forming a magnetic structure 120 in the recess H1 to make the magnetic structure 120 could be embedded in the substrate 110 (shown in FIG. 1D).

The magnetic structure 120 includes a ferromagnetic material layer 122 and at least one first hard protective layer 124 disposed on a first surface of the ferromagnetic material layer 122. The ferromagnetic material layer 122 is such as an iron core. The magnetic structure 120 further includes a second hard protective layer 126 disposed on a second surface of the ferromagnetic material layer 122, for example. In other words, the first hard protective layer 124 and the second hard protective layer 126 are respectively disposed on an upper surface and a loser surface of the ferromagnetic material layer 122. So the first hard protective layer 124 and the second hard protective layer 126 could protect and prevent the ferromagnetic material layer 122 from breaking in a pressing process. Therefore, the first hard protective layer 124 and the second hard protective layer 126 have a material of a fully hardened reactive resin having a epoxy group, wherein the reactive resin having the epoxy group has a glass transition temperature (Tg) greater than 200° C., and has a coefficient of thermal expansion (CTE) greater than or equal to that of the substrate 110.

Therefore, the step for forming the magnetic structure 120 includes forming firstly the second hard protective layer 126 formed by forming the reactive resin having the epoxy group on a bottom of the recess H1; forming the ferromagnetic material layer 122 on the second hard protective layer 126; and then forming the first hard protective layer 124 formed by forming the reactive resin having the epoxy group on the ferromagnetic material layer 122, and the magnetic structure 120 is completed.

Please refer to FIG. 1E. After forming the magnetic structure 120, the method for manufacturing the planar magnetic component further includes forming a adhesive layer 130 on the first surface Si of the substrate 110 as well as on a surface of the first hard protective layer 124, wherein the above-mentioned surface of the first hard protective layer 124 is away from the ferromagnetic material layer 122. So the first hard protective layer 124 is disposed between the adhesive layer 130 and the ferromagnetic layer 122. The adhesive layer 130 has a material of polypropylene.

Please refer to FIG. 1F. After forming the adhesive layer 130, the method for manufacturing the planar magnetic component further includes forming a second conductor layer 140 on a surface of the adhesive layer 130, wherein the above-mentioned surface of the adhesive layer 130 is away from the first hard protective layer 124 and the first surface Si of the substrate 110. The second conductor layer 140 has a material such as copper.

Next, please refer to FIG. 1G. After forming the second conductor layer 140, the method for manufacturing the planar magnetic component further includes forming a plurality of holes. As illustrated in FIG. 1G, it is understood that a plurality of holes in this embodiment is exemplified by including two holes V1, V2 and the present invention is not limited thereto. The holes V1, V2 penetrate through the second conductor layer 140, the adhesive layer 130, the magnetic structure 120, the substrate 110 and the first conductor layer 112, and then at least one wire (not shown in figures) passes through the holes V1, V2 as well as entwines the magnetic structure 120 more than one rounds, and then the planar magnetic component 100 with the above-mentioned winding structure is completed. Please refer to FIGS. 1H, 1I. The ferromagnetic material layer 122 is such as a solid cylinder 1220 or has a tube-shape 1221, and a shape of the recess H1 could be adjusted in accordance with the shape of the ferromagnetic material layer and the present invention is not limited to that shown in the figures. It is worth mentioning that if the ferromagnetic material layer 122 is a solid cylinder, and then such as an insulating layer is disposed around a side wall of the holes V1, V2 (not shown in figures). So the wire passing through the holes V1, V2 could be isolated from the magnetic structure 120 by the insulating layer.

In addition, the planar magnetic component 100 is not only adapted to be applied in producing a broadband planar transformer used in a communication connector, but also applied in producing devices used in non-Ethernet applications including applied in a set-top box, a RF router, a RF mobile device, and a consumer electronics product.

In summary, two hard protective layers respectively disposed on an upper surface and a lower surface of the ferromagnetic material layer of the planar magnetic component is provided to protect and prevent the ferromagnetic material layer from being breaking in a pressing process. So a production yield of a transformer produced with the planar magnetic component could be enhanced.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A planar magnetic component, comprising:
a substrate; and
a magnetic structure embedded in the substrate, the magnetic structure includes:
a ferromagnetic material layer; and
at least one first hard protective layer disposed on a first surface of the ferromagnetic material layer.

2. The planar magnetic component according to claim 1, wherein the magnetic structure further includes a second hard protective layer disposed at a second surface of the ferromagnetic material layer, wherein the first surface of the ferromagnetic material layer and the second surface of the ferromagnetic material layer are opposite to each other.

3. The planar magnetic component according to claim 2, wherein the first hard protective layer and the second hard protective layer have a material of a reactive resin having an epoxy group, and the ferromagnetic material layer is an iron core.

4. The planar magnetic component according to claim 3, wherein the reactive resin having the epoxy group has a glass transition temperature greater than 200° C.

5. The planar magnetic component according to claim 3, wherein the reactive resin having the epoxy group has a coefficient of thermal expansion greater than or equal to that of the substrate.

6. The planar magnetic component according to claim 1, further comprising a first conductor layer disposed on a second surface of the substrate and a second conductor layer disposed over a first surface of the substrate, wherein the first surface of the substrate and the second surface of the substrate are opposite to each other, the second surface of the substrate is away from the magnetic structure, the first surface of the substrate is close to the magnetic structure, and the first hard protective layer is disposed between the ferromagnetic material layer and the second conductor layer.

7. The planar magnetic component according to claim 6, further comprising an adhesive layer disposed between the first hard protective layer and the second conductor layer as well as disposed between the substrate and the second conductor layer.

8. The planar magnetic component according to claim 7, wherein the first conductor layer and the second conductor layer have a material of copper, and the adhesive layer has a material of polypropylene.

9. The planar magnetic component according to claim 1, further comprising a plurality of holes and at least one wire, wherein each of the hole penetrates through the second conductor layer, the adhesive layer, the magnetic structure, the substrate, and the first conductor layer, and the wire passes through the hole as well as entwines the magnetic structure, and the substrate is a printed circuit board.

10. A method for manufacturing a planar magnetic component, comprising;
providing a substrate having a first surface;
forming a recess in the substrate, wherein the recess penetrates through the first surface of the substrate; and
forming a magnetic structure in the recess, including:
forming a ferromagnetic material layer; and
forming at least one first hard protective layer on a first surface of the ferromagnetic material layer.

11. The method for manufacturing a planar magnetic component according to claim 10, wherein the substrate further includes a zeroth conductor layer disposed on the first surface of the substrate, and the method for manufacturing a planar magnetic component further comprises removing the zeroth conductor layer by an etching process before forming the recess in the substrate.

12. The method for manufacturing a planar magnetic component according to claim 10, wherein the step of forming a magnetic structure in the recess further includes forming a second hard protective layer on a second surface of the ferromagnetic material layer, wherein the first surface of the ferromagnetic material layer and the second surface of the ferromagnetic material layer are opposite to each other.

13. The method for manufacturing a planar magnetic component according to claim 12, wherein the first hard protective layer and the second hard protective layer have a material of a reactive resin having an epoxy group, and the ferromagnetic material layer is an iron core.

14. The method for manufacturing a planar magnetic component according to claim 13, wherein the reactive resin having the epoxy group has a glass transition temperature greater than 200° C.

15. The method for manufacturing a planar magnetic component according to claim 13, the reactive resin having the epoxy group has a coefficient of thermal expansion greater than or equal to that of the substrate.

16. The method for manufacturing a planar magnetic component according to claim 10, wherein the substrate further includes a first conductor layer disposed on a second surface of the substrate, the second surface of the substrate and the first surface of the substrate are opposite to each other.

17. The method for manufacturing a planar magnetic component according to claim 16, further comprising forming an adhesive layer on the first surface of the substrate as well as on a surface of the first hard protective layer away from the ferromagnetic material layer, and the first hard protective layer is disposed between the adhesive layer and the ferromagnetic material layer.

18. The method for manufacturing a planar magnetic component according to claim 17, further comprising forming a second conductor layer on a surface of the adhesive layer away from the first hard protective layer and the first surface of the substrate.

19. The method for manufacturing a planar magnetic component according to claim 18, wherein the first conductor layer and/or the second conductor layer have/has a material of copper, and the adhesive layer has a material of polypropylene.

20. The method for manufacturing a planar magnetic component according to claim 18, further comprising forming a plurality of holes, wherein each of the hole penetrates through the second conductor layer, the adhesive layer, the magnetic structure, the substrate, and the first conductor layer, and then at least one wire passes through the hole as well as entwines the magnetic structure, and the substrate is a printed circuit board.
